(19) United States
(12) Patent Application Publication
(10) Pub. No.: US 2015/0280084 A1
(43) Pub. Date: Oct. 1, 2015

(54) SEMICONDUCTOR LIGHT EMITTING DEVICE AND METHOD OF MANUFACTURING SAME

(71) Applicant: Kabushiki Kaisha Toshiba, Tokyo (JP)

(72) Inventor: Yasuharu Sugawara, Nonoichi (JP)

(21) Appl. No.: 14/482,164

(22) Filed: Sep. 10, 2014

(30) Foreign Application Priority Data
Mar. 27, 2014 (JP) 2014-065345

(51) Int. Cl. H01L 33/56; H01L 33/50; H01L 33/62

(52) U.S. Cl. CPC H01L 33/56; H01L 33/62; H01L 33/501; H01L 2933/005

(57) ABSTRACT

According to an embodiment, a semiconductor light emitting device includes a semiconductor layer, a first and a second interconnect parts and a first and a second insulating films. The semiconductor layer has a first side and a second side opposite to the first side, and includes a first conductivity type layer, a second conductivity type layer and a light emitting layer. The first interconnect part is electrically connected to the first conductivity type layer. The second interconnect part is electrically connected to the second conductivity type layer.

The first insulating film is provided between the semiconductor layer and the first interconnect part, and between the semiconductor layer and the second interconnect part. The second insulating film is in contact with the semiconductor layer on the first side, and has a density different from that of the first insulating film.

### CROSS-REFERENCE TO RELATED APPLICATIONS

This application is based upon and claims the benefit of priority from Japanese Patent Application No.2014-065345, filed on Mar. 27, 2014; the entire contents of which are incorporated herein by reference.

### FIELD

Embodiments are related generally to a semiconductor light emitting device and a method of manufacturing the same.

### BACKGROUND

Downsizing a semiconductor light emitting device is in progress, and makes it possible to achieve a chip-size device. Such a device includes a semiconductor layer separated from a growth substrate, and a resin covering a periphery thereof. Then, it is preferable to interpose an insulating film, such as a silicon oxide film, between the semiconductor layer and the resin in order to increase adhesion strength therebetween. The insulating film, however, may induce stress in the semiconductor layer, and reduce a manufacturing yield of the semiconductor light emitting device.

### BRIEF DESCRIPTION OF THE DRAWINGS

FIG. 1 is a schematic cross-sectional view showing an example of a semiconductor light emitting device according to an embodiment;

FIG. 2 is a graph showing an example of a property of an insulating film according to the embodiment;

FIGS. 3A and 3B are schematic plan views showing the semiconductor light emitting device according to the embodiment: and

FIGS. 4A to 10B are schematic cross-sectional views showing an example of a manufacturing process of the semiconductor light emitting device according to the embodiment.

### DETAILED DESCRIPTION

According to an embodiment, a semiconductor light emitting device includes a semiconductor layer, a first interconnect part, a second interconnect part, a first insulating film and a second insulating film. The semiconductor layer has a first side and a second side opposite to the first side, and includes a first conductivity type layer, a second conductivity type layer, and a light emitting layer between the first conductivity type layer and the second conductivity type layer. The first interconnect part is provided on the second side and electrically connected to the first conductivity type layer. The second interconnect part is provided on the second side, and electrically connected to the second conductivity type layer. The first insulating film is provided between the semiconductor layer and the first interconnect part, and between the semiconductor layer and the second interconnect part. The second insulating film is in contact with the first side of the semiconductor layer on the first side, and has a density different from a density of the first insulating film.

Hereinafter, with reference to drawings, embodiments are described. In each drawing, the same symbol is attached to the same element.

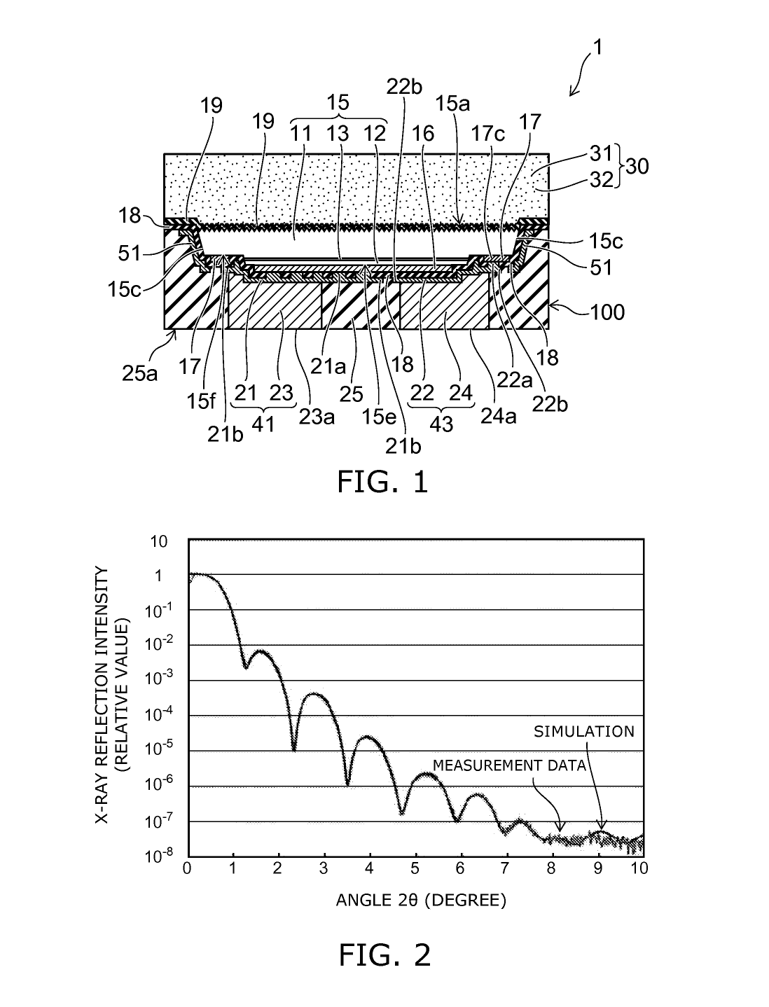

FIG. 1 is a schematic cross-sectional view illustrating a semiconductor light emitting device 1 of an embodiment.

FIG. 2 is a graph illustrating characteristics of an insulating film in the embodiment.

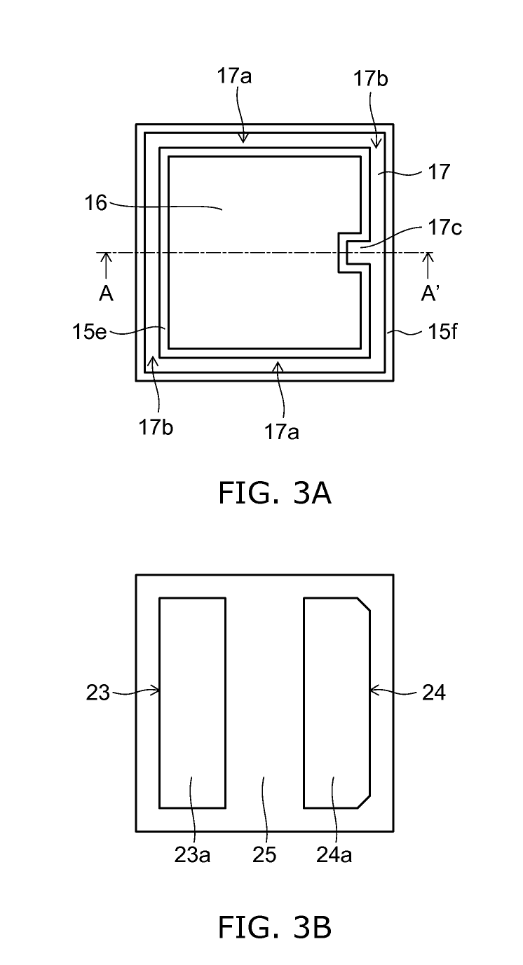

FIGS. 3A and 3B are schematic plan views illustrating the semiconductor light emitting device 1.

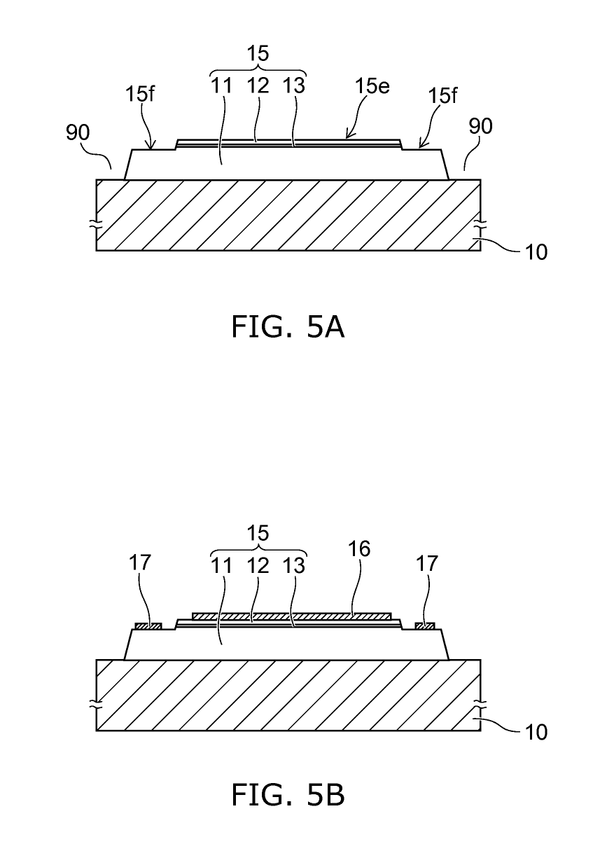

FIG. 1 is a section view along an A-A′ line shown in FIG. 3A. FIG. 3A and FIG. 3B are plan views showing a lower face side of the semiconductor light emitting device 1 shown in FIG. 1. FIG. 3A shows a surface of the semiconductor light emitting device 1 after temporarily removing a structure provided on the lower face side thereof, which corresponds to an upper face in FIG. 5B, to be described later.

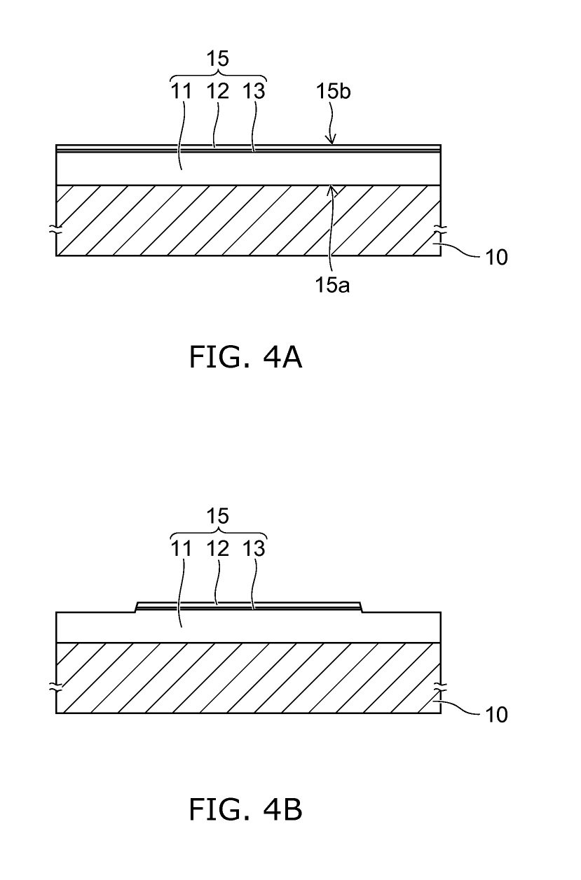

The semiconductor light emitting device 1 includes a semiconductor layer 15 that includes a light emitting layer 13. The semiconductor layer 15 has a first side 15a and a second side 15b opposite thereto (see FIG. 4A). Further, the semiconductor layer 15 includes a layer of a first conductivity type (hereinafter, n-type layer 11) and a layer of a second conductivity type (hereinafter, p-type layer 12). The light emitting layer 13 is provided between the n-type layer 11 and the p-type layer 12.

In the example, the first conductive type is described as an n-type and the second conductivity type as a p-type, but the embodiment is not limited thereto. Alternatively, the first conductive type may be a p-type layer, and the second conductivity type may be an n-type layer.

As shown in FIG. 5A, the second side 15b of the semiconductor layer 15 has a portion including the light emitting layer 13 (hereinafter, light-emitting region 15e) and a portion not including the light emitting layer 13 (hereinafter, non light-emitting region 15f). The light-emitting region 15e is a portion of the semiconductor layer 15, which has a stacked structure including the light emitting layer 13. The non-emitting region 15f is the other portion of the semiconductor layer 15, in which the light emitting layer 13 is not stacked. The light emitting region 15e has the stacked structure capable of extracting light emitted from the light emitting layer 13.

The second side 15b of the semiconductor layer 15 is formed to have projecting part and depressed part. The projecting part thereof is the light-emitting region 15e and the depressed part is the non light-emitting region 15f. In the example, the light emitting region 15e includes the p-type layer 12 on the second side 15b, and a p-side electrode 16 is provided on the surface of the p-type layer 12. The non light-emitting region 15f includes the n-type layer 11, and an n-side electrode 17 is provided on the surface of the second side 15b of the n-type layer 11.

Further, the semiconductor light emitting device 1 includes a p-side interconnect part 41 (second interconnect part) and an n-side interconnect part 43 (first interconnect part) provided on the second side 15b. The p-side interconnect part 41 includes a p-side interconnect layer 21 and a p-side metal pillar 23, and is electrically connected to the p-type layer 12 via the p-side electrode 16. The n-side interconnect part 43 includes an n-side interconnect layer 22 and an n-side metal pillar 24 and is electrically connected to the n-type layer 11 via the n-side electrode 17.

A first insulating film (hereinafter, insulating film 18) is provided between the semiconductor layer 15 and the p-side interconnect part 41, and between the semiconductor layer 15 and the n-side interconnect part 43. A second insulating film (hereinafter, insulating film 19) is provided on the side of the first side 15a. The insulating film 19 is in contact with the semiconductor layer 15 on the first side 15a, and has a different density from that of the insulating film 18.

Here, the “density” is a measure for characterizing thin film. For example, a silicon oxide film or a silicon nitride film may be characterized to have a high density, when the density of silicon atoms therein is high. In other words, the average distance between silicon atoms in the film is narrow, when the “density” is high, and the average distance therebetween is wide, when the “density” is low. Further, when the number of bonds between the silicon atom and the oxygen atom or between the silicon atom and the nitrogen atom is large in the film, the “density” is high, and when the number of bonds therebetween is small, the “density” is low.

For example, FIG. 2 shows the result of analyzing a silicon oxide film by using XRR (X-ray Reflectivity). The vertical axis represents the intensity of the reflected X-ray, and the horizontal axis represents the angle 28.

In the XRR method, the intensity of the X-ray is measured, which is totally reflected at the surface of a sample in which an insulating film is formed. Then, a simulation is performed to fit theoretical values to the measurement data. FIG. 2 shows the measurement data of the totally reflected X-ray and the simulation result using the incidence angle θ as variable. Thus, it is possible to calculate the density (g/cm³) of the insulating film based on the simulation result. For example, the density of the silicon oxide film formed using the plasma CVD (Plasma enhanced Chemical Vapor Deposition) method is 2.23 g/cm³. When using the sputter method, the density of the silicon oxide film is 2.25 g/cm³, which is higher than that of the silicon oxide film formed by the PECVD method. In this manner, by using the XRR method, it is possible to determine the density of an insulating film.

The semiconductor layer 15 further has a side surface 15c connecting the first side 15a and the second side 15b. The insulating film 18 covers the side surface 15c. In other words, the insulating film 18 and the insulating film 19 cover the entire surface of the semiconductor layer 15.

In the specification, “cover” is not limited to the case where “what covers” directly contacts “what is covered”, and the “what covers” may cover the “what is covered” via another element.

As shown in FIG. 1, a support body 100 is provided on the second side 15b of the semiconductor layer 15. The support body 100 includes the p-side metal pillar 23, the n-side metal pillar 24, and a resin layer 25. A light emitting body that includes the semiconductor layer 15, the p-side electrode 16, and the n-side electrode 17 is supported by the support body 100 provided on the second side 15b.

The resin layer 25 is provided between the p-side interconnect part 41 and the n-side interconnect part 43 on the second side 15b. Further, the resin layer 25 covers the second side 15b and the side surface 15c of the semiconductor layer 15 via the insulating film 18.

In the semiconductor light emitting device 1, a voltage is applied between the p-side interconnect part 41 and the n-side interconnect part 43, and then, an electric current is supplied to the light emitting layer 13 via the p-side electrode 16 and the n-side electrode 17. Due to this, the light emitting layer 13 emits light and the light emitted from the light emitting layer 13 is extracted outward from the first side 15a.

On the first side 15a, a phosphor layer 30 is provided as an optical layer giving optical characteristics desired to the emitted light of the semiconductor light emitting device 1. The phosphor layer 30 includes a plurality of phosphors 31 in the form of a particle. The phosphor 31 is excited by the light emitted from the light emitting layer 13 and emits light having a wavelength different from a wavelength of the excitation light.

The plurality of phosphors 31 are joined into one body with a bonding material 32. The bonding material 32 has transparency against the light emitted from the light emitting layer 13 and the light emitted from the phosphor 31. Here, “transparency” is not limited to the case where transmitting 100% of the lights, and may include the case where part of light is absorbed.

FIG. 3A is a schematic plan view illustrating an arrangement of the p-side electrode 16 and the n-side electrode 17. In other words, FIG. 3A shows a virtual face on the second side 15b of the semiconductor light emitting device 1, where the resin layer 25, the p-side interconnect part 41, the n-side interconnect part 43, and the insulating film 18 are removed therefrom.

As shown in FIG. 3A, the n-side electrode 17 is provided to surround the p-side electrode 16. In other words, the non light-emitting region 15f is provided to surround the light-emitting region 15e. Then, the p-side electrode 16 is formed on the light emitting region 15e, and the n-side electrode 17 is formed to surround the p-side electrode 16 on the non light-emitting region 15f.

On the second side 15b, the light emitting region 15e is provided so that an area thereof is larger than an area of the non light-emitting region 15f. Further, an area of the p-side electrode 16 provided on the light emitting region 15e is larger than an area of the n-side electrode 17 provided on the non light-emitting region 15f. Thereby, a wide light emitting face is obtained and it is possible to increase the light output.

As shown in FIG. 3A, the n-side electrode 17 is formed in a shape on the second side 15b, in which a plurality of straight line parts 17a extending in different directions are joined with corner parts 17b. The entire face of the p-side electrode 16 is in contact with the surface of the p-type layer 12.

In the example shown in FIG. 3A, for example, the four straight line parts 17a form a rectangular contour connected via the four corner parts 17b. The corner part 17b may have a curvature.

Further, one of straight line parts 17a is provided with a contact part 17c protruding in the width direction of the straight line part 17a. In other words, the contact part 17c is made wider in the straight line part 17a. As described later, a via-portion 22a of the n-side interconnect layer 22 is connected to the contact part 17c.

On the second side 15b of the semiconductor layer 15, the insulating film 18 covers the p-side electrode 16 and the n-side electrode 17 as shown in FIG. 1. The insulating film 18 is, for example, an inorganic insulating film, such as a silicon oxide film. The insulating film 18 is provided also on the side surface of the light emitting layer 13 and the side surface of the p-type layer 12, and covers the side surfaces.

Further, the insulating film 18 is provided also on the side surface 15c (i.e. the side surface of the n-type layer 11) continuing from the first side 15a in the semiconductor layer 15. The insulating film 18 covers the side surface 15c.

Furthermore, the insulating film 18 is provided also around the side surface 15c of the semiconductor layer 15. The insulating film 18 is provided around the side surface 15c, and extends from the side surface 15c toward the side opposite to the side surface 15c on the first side 15a.

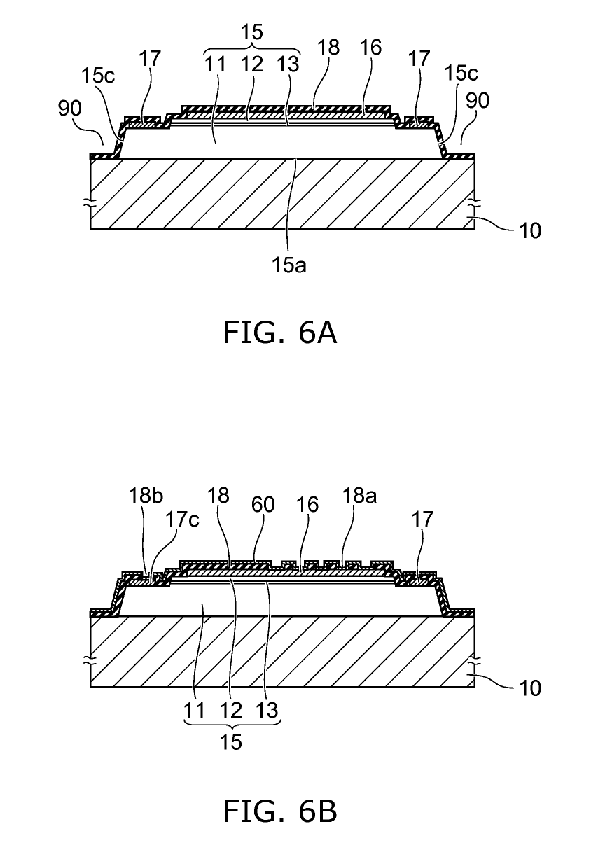

On the insulating film 18, the p-side interconnect layer 21 and the n-side interconnect layer 22 are provided to be separate from each other. As shown in FIG. 6B, a plurality of first openings 18a and a second opening 18b are formed in the insulating film 18. The first openings 18a is in communication with the p-side electrode 16, and a second opening 18b is in communication with the contact part 17c of the n-side electrode 17. Alternatively, a first opening 18a that has larger opening area may be formed to be in communication with the p-side electrode 18 instead of the first openings 18a.

The p-side interconnect layer 21 is provided on the insulating film 18 and inside the first openings 18a. The p-side interconnect layer 21 has via-portions 21a that are electrically connected with the p-side electrode 16 in the first openings 18a.

The n-side interconnect layer 22 is provided on the insulating film 18 and inside the second opening 18b. The n-side interconnect layer 22 has a via-portion 22a that is electrically connected with the contact part 17c of the n-side electrode 17 in the second opening 18b.

The p-side interconnect layer 21 and the n-side interconnect layer 22 extends on the insulating film 18 occupying most of the surface on the second side 15b.

Further, a metal film 51 covers the side surface 15c of the semiconductor layer 15 via the insulating film 18. The metal film 51 is not in contact with the side surface 15c and is not electrically connected to the semiconductor layer 15. The metal film 51 is separated from the p-side interconnect layer 21 and the n-side interconnect layer 22. The metal film 51 has the property of reflecting the light emitted from the light emitting layer 13 and the light emitted from the phosphor 31.

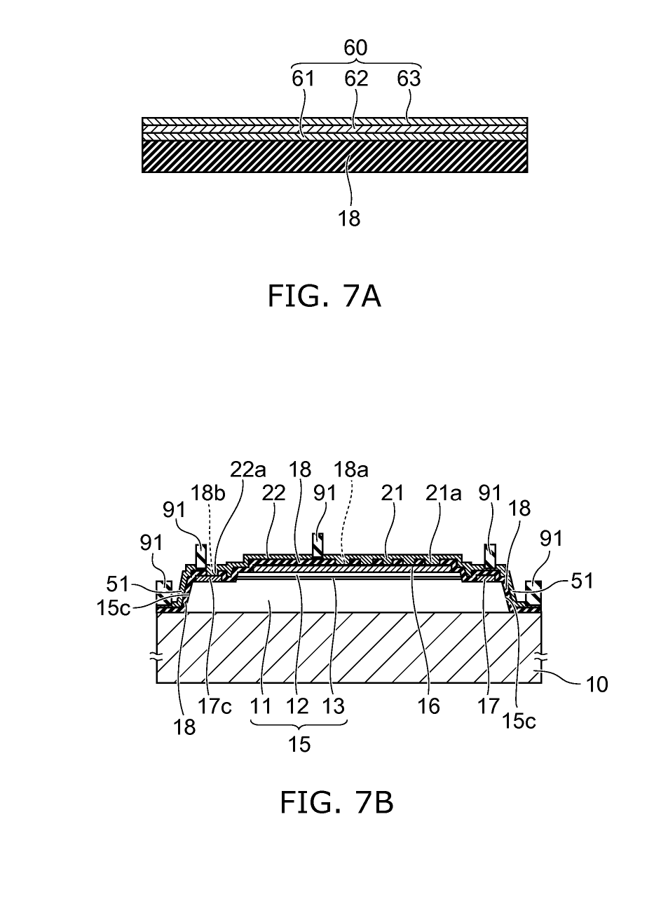

The metal film 51, the p-side interconnect layer 21, and the n-side interconnect layer 22 may include copper films simultaneously formed on a common underlying metal film 60 using the plating method, for example, as described later in FIG. 7A.

The underlying metal film 60 has an aluminum (Al) film 61, a titanium (Ti) film 62, and a copper (Cu) film 63 stacked in order from the insulating film 18 side. The aluminum film 61 acts as a reflection film, and the copper film 63 is used as a seed layer. The titanium film 62 that is wettable to aluminum and copper acts as an adhesion layer.

For example, a thickness of the underlying metal film 60 is about 1 μm and a thickness of each of the metal film 51, the p-side interconnect layer 21, and the n-side interconnect layer 22 is several μm.

Around the side surface 15c of the semiconductor layer 15, a plating film (copper film) may not be formed on the underlying metal film 60. For example, the metal film 51 may be a part of the underlying metal film 60. The metal film 51 may include at least the aluminum film 61. Thereby, the metal film 51 has a high reflectance for the lights emitted from the light emitting layer 13 and the phosphor 31.

Further, the aluminum film 61 is also provided under the p-side interconnect layer 21 and the n-side interconnect layer 22, and thus, the aluminum film (reflective film) 61 covers most of the surface on the second side 15b. Thereby, it is possible to increase amount of the light propagating toward the phosphor layer 30 side.

The p-side metal pillar 23 is provided on the p-side interconnect layer 21 on the surface thereof opposite to the semiconductor layer 15. The p-side interconnect layer 21 and the p-side metal pillar 23 form the p-side interconnect part 41.

The n-side metal pillar 24 is provided on the n-side interconnect layer 22 on the surface thereof opposite to the semiconductor layer 15. The n-side interconnect layer 22 and the n-side metal pillar 24 form the n-side interconnect part 43.

The resin layer 25 is provided between the p-side interconnect part 41 and the n-side interconnect part 43, and acts as an insulating layer. The resin layer 25 contacts the side surface of the p-side metal pillar 23 and the side surface of the n-side metal pillar 24. In other words, the resin layer 25 is filled between the p-side metal pillar 23 and the n-side metal pillar 24.

The resin layer 25 is provided in contact with the insulating film 18 between the p-side interconnect layer 21 and the n-side interconnect layer 22, between the p-side interconnect layer 21 and the metal film 51, and between the n-side interconnect layer 22 and the metal film 51. Further, the resin layer 25 is provided also around the side surface 15c of the semiconductor layer 15 and covers the metal film 51.

The end (face) of the p-side metal pillar 23 opposite to the p-side interconnect layer 21 is exposed in the resin layer 25, and serves as a p-side external terminal 23a capable of being connected with an external circuit, such as a mounting substrate. The end (face) of the n-side metal pillar 24 opposite to the n-side interconnect layer 22 is exposed in the resin layer 25, and serves as an n-side external terminal 24a capable of being connected with the external circuit. The p-side external terminal 23a and the n-side external terminal 24a are connected via a solder or a conductive bonding material to land patterns in a mounting substrate.

FIG. 3B is a schematic plan view illustrating a lower face 25a on the second side 15b of the semiconductor light emitting device 1.

As shown in FIG. 3B, the p-side external terminal 23a and the n-side external terminal 24a are exposed in the same face of the resin layer 25 (i.e. the lower face 25a in FIG. 1), and separated from each other.

The semiconductor light emitting device 1 has, for example, an external shape of a square. A distance between the p-side external terminal 23a and the n-side external terminal 24a exposed in the resin layer 25 is wider than a distance between the p-side interconnect layer 21 and the n-side interconnect layer 22 on the insulating film 18 (see FIG. 1). The distance between the p-side external terminal 23a and the n-side external terminal 24a is made wider than the expanding width of solder while mounting. Thereby, it is possible to avoid a short circuit via the solder between the p-side external terminal 23a and the n-side external terminal 24a.

Further, it is possible to reduce the distance between the p-side interconnect layer 21 and the n-side interconnect layer 22 to the limit of manufacturing accuracy thereof. Then, it becomes possible to increase an area of the p-side interconnect layer 21 and a contact area between the p-side interconnect layer 21 and the p-side metal pillar 23. Thereby, it is possible to enhance heat dissipation from the light emitting layer 13 through the p-side interconnect part 41.

An area in which the p-side interconnect layer 21 contacts the p-side electrode 16 through the via-portions 21a is larger than an area in which the n-side interconnect layer 22 contacts the n-side electrode 17 through the via-portion 22a. Due to this, it is possible to make uniform the distribution of the current flowing through the light emitting layer 13.

It is possible to make an area of the n-side interconnect layer 22 extending on the insulating film 18 larger than an area of the n-side electrode 17. Then, it is possible to make an area of the n-side metal pillar 24 provided on the n-side interconnect layer 22 (i.e. the area of the n-side external terminal 24a) larger than the area of the n-side electrode 17. Thus, it becomes possible to reduce the area of the n-side electrode 17, maintaining the area of the n-side external terminal 24a sufficient for bonding with high reliability. In other words, it becomes possible to increase the output power of light by reducing an area of the non light-emitting region 15f and by increasing an area of the light-emitting region 15e in the semiconductor layer 15.

The n-type layer 11 is electrically connected to the n-side metal pillar 24 via the n-side electrode 17 and the n-side interconnect layer 22. The p-type layer 12 is electrically connected to the p-side metal pillar 23 via the p-side electrode 16 and the p-side interconnect layer 21.

A thickness of the p-side metal pillar 23 is greater than a thickness of the p-side interconnect layer 21 in a direction in which the p-side interconnect layer 21 and the p-side external terminal 23a are stacked. A thickness of the n-side metal pillar 24 is greater than a thickness of the n-side interconnect layer 22 in a direction in which the n-side interconnect layer 22 and the n-side external terminal 24a are stacked. Each of the p-side metal pillar 23, the n-side metal pillar 24, and the resin layer 25 has greater thickness than a thickness of the semiconductor layer 15.

An aspect ratio (i.e. the ratio of thickness to planar size) of the metal pillar 23, 24 may be not less than one or may be less than one. In other words, the thickness of the metal pillar 23, 24 may be greater than the planar size thereof or may be less.

A thickness of the support body 100 including the p-side interconnect layer 21, the n-side interconnect layer 22, the p-side metal pillar 23, the n-side metal pillar 24, and the resin layer 25 is greater than a thickness of the phosphor (LED element) including the semiconductor layer 15, the p-side electrode 16, and the n-side electrode 17.

As will be described later, the semiconductor layer 15 is formed on the substrate by the epitaxial growth method. The substrate is removed after forming the support body 100, and the semiconductor layer 15 does not include the substrate on the first side 15a. The semiconductor layer 15 is not supported by a substrate having high rigidity, and supported by the support body 100 made of a composite body of the metal pillars 23, 24 and the resin layer 25.

It is possible to use the material, such as copper, gold, nickel, silver and the like for the p-side interconnect part 41 and the n-side interconnect part 43. Copper is preferable among these materials, since it is possible to obtain good thermal conductivity and high migration resistance, and to improve adhesion strength to the insulating material.

The resin layer 25 may reinforce the p-side metal pillar 23 and the n-side metal pillar 24. The resin layer 25 preferably has a thermal expansion coefficient equivalent to or close to the thermal expansion coefficient of the mounting substrate. Such the resin layer 25 may be made mainly of an epoxy resin, a silicone resin, and a fluorine resin, for example.

The base resin forming the resin layer 25 may include a light shielding material, such as light absorbing material, light reflecting material, and light scattering material, providing light shielding properties against the light emitted from the light emitting layer 13. Thus, it is possible to suppress light leak from the side face and the mounting face of the support body 100.

During mounting the semiconductor light emitting device 1 via the solder or the like, which connects the p-side external terminal 23a and the n-side external terminal 24a to the lands on the mounting substrate, heat cycle therethrough may generates the stress in the semiconductor layer 15. The p-side metal pillar 23, the n-side metal pillar 24, and the resin layer 25 may absorb and relax the stress. It is preferable to make the resin layer 25 more flexible than the semiconductor layer 15, facilitating the stress relaxation in the support body 100.

Since the metal film 51 is separated from the p-side interconnect part 41 and the n-side interconnect part 43, the stress applied to the p-side metal pillar 23 and the n-side metal pillar 24 is not transferred to the metal film 51 during the mounting process. Thus, it is possible to avoid peeling of the metal film 51. Further, it is possible to suppress the stress applied to the semiconductor layer 15 through the side surface 15c.

As described later, the substrate used to form the semiconductor layer 15 is removed therefrom, reducing the height of the semiconductor light emitting device 1. Further, it is possible to form a fine structure having inequalities on the first side 15a of the semiconductor layer 15 after removing the substrate, and it becomes possible to improve light extraction efficiency.

For example, we etching using an alkali-based solution forms the fine structure on the first side 15a. Thus, it is possible to improve light extraction efficiency by reducing the total reflection of the light emitted from the light emitting layer 13 on the first side 15a.

After removing the substrate, the phosphor layer 30 is formed on the first side 15a via the insulating film 19. The insulating film 19 serves as an adhesion film, improving adhesion strength between the semiconductor layer 15 and the phosphor layer 30. For example, a silicon oxide film, a silicon nitride film, or aluminum oxide (i.e. alumina) may be used for the insulating film 19.

The phosphor layer 30 has a structure in which particles of phosphor 31 are combined with the bonding material 32. The bonding material 32 is, for example, a silicone resin. The particles of phosphor 31 are dispersed in a silicone resin.

The phosphor layer 30 is formed also around the semiconductor layer 15, extending from the side surface 15c. Thus, a planar size of the phosphor layer 30 is larger than a planar size of the semiconductor layer 15. The phosphor layer 30 is provided on the insulating film 18 and the insulating film 19 around the semiconductor layer 15.

The phosphor layer 30 is provided on the first side 15a of the semiconductor layer 15, and not to reach the side surface 15c and the second side 15b of the semiconductor layer 15. The phosphor layer 30 is not provided on the side surface of the support body 100. The side surface of the phosphor layer 30 aligns with the side surface of the support body 100 (i.e. the side surface of the resin layer 25).

In other words, the semiconductor light emitting device 1 of the embodiment is a device downsized to a chip size. Then, it becomes possible to provide large flexibility in the applications thereof, such as a structural design of a lighting device and the like for example.

It is possible to reduce the manufacturing cost, since the phosphor layer 30 is not formed without avail on the mounting face side from which the light is not extracted outward. Further, the semiconductor light emitting device 1 maintains heat dissipating properties despite being formed in compact size, since it is possible to dissipate the heat from the light emitting layer 13 to the mounting substrate side via the p-side interconnect layer 21 and the n-side interconnect layer 22 covering the semiconductor layer 15 on the second side 15b even if the substrate is removed from the first side 15a.

In the typical flip-chip mounting device, the phosphor layer is formed to cover the whole LED chip after mounting the LED chip on the mounting substrate via bumps and like. Further, the underfill resin is provided between the LED chip and the mounting substrate.

In contrast to this, the light emitting device 1 according to the embodiment comprises the resin layer 25 before mounting around the p-side metal pillar 23 and around the n-side metal pillar 24. The resin layer 25 different from the phosphor layer 30 makes it possible to give the characteristics suitable for relaxing the stress on the mounting face side. Further, the resin layer 25 provided on the mounting face side serves as the underfill resin after mounting.

A layer is provided on the first side 15a, which is designed by giving priority to the light extraction efficiency, the color conversion efficiency, the light distribution characteristics and the like, and another layer is provided on the mounting face side (i.e. the second side 15b), which is designed by giving priority to demands for the support body that substitutes the substrate, such as the stress relaxation in the mounting process. For example, the resin layer 25 has a structure, wherein the base resin includes filler, such as silica particles, with a high density, and is adjusted to have appropriate hardness as the support body.

The light emitted from the light emitting layer 13 enters the phosphor layer 30 on the first side 15a, and part of the light excites the phosphor 31. Thus, the device radiates, for example, white light obtained by mixing the other part of the light emitted from the light emitting layer 13 and the light emitted from the phosphor 31.

When the substrate is not removed on the first side 15a, less light enters the phosphor layer 30, and the other light leaks outward from the side surface of the substrate. The light that leaks from the side surface of the substrate may have strong hue contrast, and thus, cause color breakup and color unevenness, inducing a phenomenon, such as a blue ring on the outer edge side of the phosphor layer 30 in a view of the upper face thereof.

In contrast to this, according to the embodiment, there is no substrate between the first side 15a and the phosphor layer 30, and thus, it is possible to suppress color breakup and color unevenness due to the light leak from the side face of the substrate, which has the strong hue contrast.

Further, according to the embodiment, the metal film 51 is provided via the insulating film 18 on the side surface 15c of the semiconductor layer 15. The light that propagates from the light emitting layer 13 toward the side surface 15c of the semiconductor layer 15 is reflected from the metal film 51 and does not leak outward. Thus, in addition to the advantage for removing the substrate on the first side 15a, the metal film 51 may suppress the color breakup and color unevenness due to the light leak from the side surface side of the semiconductor light emitting device 1.

The semiconductor layer 15 is provided so that a cross-sectional area parallel to the first side 15a becomes larger in the direction from the second side 15b to the first side 15a, for example. Then, the metal film 51 is provided so as to gradually spread in the direction from the second side 15b to the first side 15a. The light reflected from the metal film 51 propagates in the direction of the first side 15a. Thereby, it is possible to increase the output power of light in the semiconductor light emitting device 1.

It may also be possible to provide the metal film 51 to extend toward the outside of the semiconductor light emitting device around the side surface 15c of the semiconductor layer 15. In other words, part of the metal film 51 is provided around the side surface 15c of the semiconductor layer 15, facing part of the phosphor layer 30 that extends outward from the side surface 15c on the first side 15a.

It is possible in the end portion of the semiconductor light emitting device 1 to return the light that is emitted from the phosphor 31 and propagates toward the support body 100 by reflecting from the metal film 51 toward the phosphor layer 30 side.

Accordingly, it is possible in the end part of the semiconductor light emitting device 1 to prevent the light of the phosphor 31 from being absorbed and lost in the resin layer 25, and to improve the light extraction efficiency from the phosphor layer 30.

The insulating film 18 provided between the metal film 51 and the side surface 15c of the semiconductor layer 15 prevents the metal included in the metal film 51 from diffusing to the semiconductor layer 15. Thus, it is possible to prevent the semiconductor layer 15 from and deteriorating the light emitting properties due to the metal contamination.

Further, the insulating films 18, 19 provided between the metal film 51 and the phosphor layer 30 enhance the adhesion between the metal film 51 and the base resin of the phosphor layer 30.

The insulating film 18 and the insulating film 19 are, for example, an inorganic insulating film, such as a silicon oxide film, a silicon nitride film, and aluminum oxide film. In other words, the inorganic insulating films covers the semiconductor layer 15 on the first side 15a and the second side 15b, the side surface 15c of the n-type layer 11, the side surface of the p-type layer 12, and the side surface of the light emitting layer 13. The inorganic insulating film surrounds the semiconductor layer 15 and blocks the semiconductor layer 15 from metal, moisture, etc.

Next, the method of manufacturing the semiconductor light emitting device is described with reference to FIG. 4A to FIG. 10B. Each cross-sectional view of FIG. 4A to FIG. 10B corresponds to the cross-section shown in FIG. 1, i.e. the cross-section along the A-A line in FIG. 3A.

As shown in FIG. 4A, for example, the light emitting layer 13, and the p-type layer 12 are epitaxially grown in order on the major surface of a substrate 10, the n-type layer 11 using the MOCVD (metal organic chemical vapor deposition) method.

In the semiconductor layer 15, a side on the substrate 10 side is the first side 15a, and another side opposite to the substrate 10 side is the second side 15b.

The substrate 10 is, for example, a silicon substrate. Alternatively, the substrate 10 may be a sapphire substrate. The semiconductor layer 15 is, for example, a nitride semiconductor layer including gallium nitride (GaN).

The n-type layer 11 includes, for example, a buffer layer provided on the major surface of the substrate 10 and an n-type GaN layer provided on the buffer layer. The p-type layer 12 has, for example, a p-type AlGaN layer provided on the light emitting layer 13 and a p-type GaN layer provided thereon. The light emitting layer 13 has an MQW (Multiple Quantum well) structure and, for example, emits light having a peak wavelength in a wavelength range of 430 to 470 nm.

FIG. 4B shows a state where the p-type layer 12 and the light emitting layer 13 are removed selectively. For example, by the RIE (Reactive Ion Etching) method, the p-type layer 12 and the light emitting layer 13 are etched selectively and the n-type layer 11 is exposed.

Next, as shown in FIG. 5A, the n-type layer 11 is removed selectively, and a groove 90 is formed. On the major surface of the substrate 10, the groove 90 divides the semiconductor layer 15 into a plurality of pieces. The groove 90 is formed, for example, into a lattice-shaped pattern on the substrate 10. It is preferable to provide the groove 90 to have a shape such that the width thereof reduces toward the bottom. For example, the groove 90 is formed using the isotropic etching condition of RIE.

The groove 90 penetrates through the semiconductor layer 15 and reaches the substrate 10. The substrate 10 may also be slightly etched depending on the etching conditions, and the groove 90 may be etched downward such that the bottom of the groove 90 locates at a level lower than the interface between the substrate 10 and the semiconductor layer 15. It may also be possible to form the groove 90 after forming the p-side electrode 16 and the n-side electrode 17.

As shown in FIG. 5B, the p-side electrode 16 is formed on the surface of the p-type layer 12. Further, the n-side electrode 17 is formed on a portion of the n-type layer 11 in which the p-type layer 12 and the light emitting layer 13 are removed selectively.

The p-side electrode 16 is formed on a portion in which the light emitting layer 13 is stacked on the n-type layer 11. The p-side electrode 16 includes a reflection film that reflects the light emitted from the light emitting layer 13. For example, the p-side electrode 16 includes silver, silver alloy, aluminum, aluminum alloy, etc. Further, the p-side electrode 16 includes a metal protection film (i.e. a barrier metal), which prevents the reflection film from sulfurization and oxidation.

Next, as shown in FIG. 6A, the insulating film 18 is formed to cover the structure provided on the substrate 10. The insulating film 18 covers the second side 15b of the semiconductor layer 15, the p-side electrode 16, and the n-side electrode 17. Further, the insulating film 18 covers the side surface 15c continuing to the first side 15a of the semiconductor layer 15. Furthermore, the insulating film 18 is also formed on the surface of the substrate 10 in the bottom portion of the groove 90.

The insulating film 18 is, for example, a silicon oxide film or a silicon nitride film formed by the PECVD method. It is preferable to form the insulating film 18 at lower temperatures so that the p-side electrode 16 and the n-side electrode 17 are not changed in properties. The density of the insulating film 18 is reduced compared to a density of the film grown at higher temperatures by the thermal CVD method, for example. Thus, it becomes possible to relax the stress due to warp of a wafer and the like in the subsequent manufacturing processes.

The first openings 18a and the second opening 18b are formed in the insulating film 18 as shown in FIG. 6B by the we etching using a resist mask. The first openings 18a reach the p-side electrode 16, and the second opening 18b reaches the contact part 17c of the n-side electrode 17.

Next, as shown in FIG. 6B, the underlying metal film 60 is formed on the surface of the insulating film 18, on the inner surface (i.e. a sidewall and a bottom) of the first opening 18a, and on the inner surface (sidewall and bottom) of the second opening 18b. The underlying metal film 60 includes the aluminum film 61, the titanium film 62, and the copper film 63 as shown in FIG. 7A. The underlying metal film 60 is formed by, for example, the sputter method.

Next, after selectively forming a resist mask 91 shown in FIG. 7B, the p-side interconnect layer 21, the n-side interconnect layer 22, and the metal film 51 are formed on the underlying metal film 60 by the electrolytic copper plating method using the copper film 63 of the underlying metal film 60 as a seed layer.

The p-side interconnect layer 21 has portions formed in the first openings 18a and electrically connected with the p-side electrode 16. The n-side interconnect layer 22 has a portion formed in the second opening 18b and electrically connected with the contact part 17c of the n-side electrode 17.

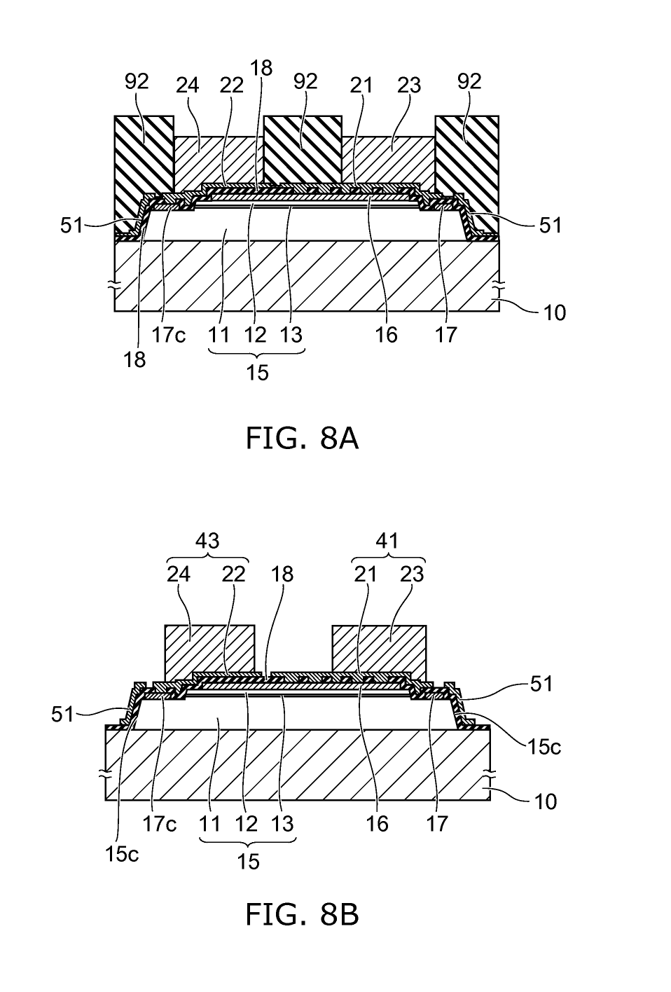

Next, after removing the resist mask 91 by using, for example, a solvent or oxygen plasma, a resist mask 92 shown in FIG. 8A is formed selectively. Alternatively, it may also be possible to form the resist mask 92 without removing the resist mask 91.

After forming the resist mask 92, the p-side metal pillar 23 and the n-side metal pillar 24 are formed by the electrolytic copper plating method using the p-side interconnect layer 21 and the n-side interconnect layer 22 as a seed layer.

The p-side metal pillar 23 is formed on the p-side interconnect layer 21. The p-side interconnect layer 21 and the p-side metal pillar 23 are joined into one body when using the same copper material therefor. The n-side metal pillar 24 is formed on the n-side interconnect layer 22. The n-side interconnect layer 22 and the n-side metal pillar 24 are joined into one body when using the same copper material therefor.

The resist mask 92 is removed by using, for example, a solvent or oxygen plasma. The p-side interconnect layer 21 and the n-side interconnect layer 22 are electrically connected via the underlying metal film 60 at this step of the manufacturing process. The p-side interconnect layer 21 and the metal film 51 are also electrically connected via the underlying metal film 60, and the n-side interconnect layer 22 and the metal film 51 are also electrically connected via the underlying metal film 60.

Then, the underlying metal film 60 are removed by etching between the p-side interconnect layer 21 and the n-side interconnect layer 22, between the p-side interconnect layer 21 and the metal film 51, and between the n-side interconnect layer 22 and the metal film 51.

As shown in FIG. 8B, the electrical connections are vanished between the p-side interconnect layer 21 and the n-side interconnect layer 22, between the p-side interconnect layer 21 and the metal film 51, and between the n-side interconnect layer 22 and the metal film 51.

The metal film 51 formed around the side surface 15c of the semiconductor layer 15 is electrically floating and does not act as an electrode. The metal film 51 serves as a reflection film. When the metal film 51 includes at least the aluminum film 61, a demand for the reflection film may be satisfied.

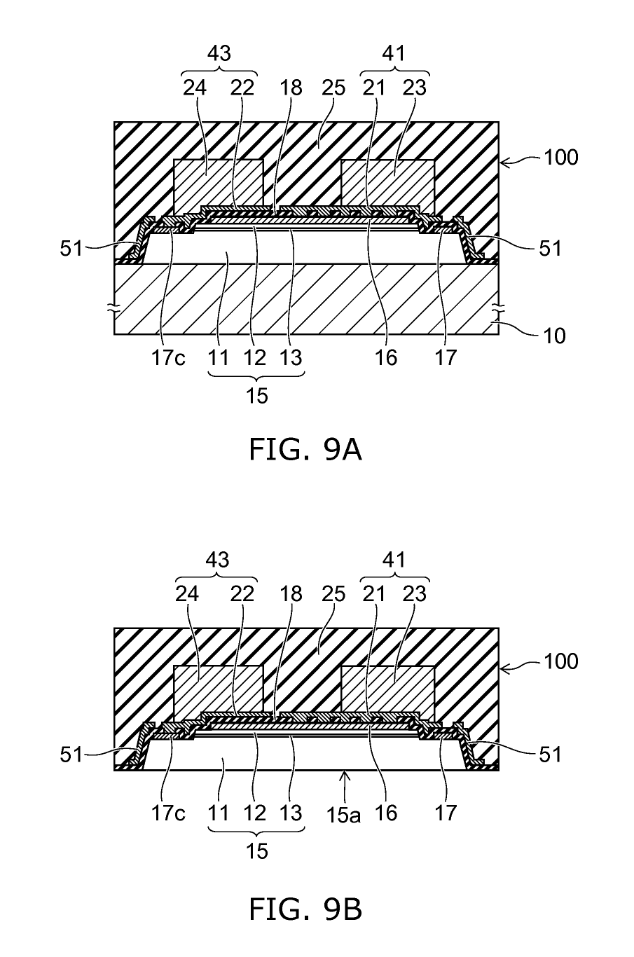

Next, the resin layer 25 shown in FIG. 9A is formed on the structure shown in FIG. 8B. The resin layer 25 covers the p-side interconnect part 41 and the n-side interconnect part 43. Further, the resin layer 25 covers the metal film 51.

The resin layer 25 is included in the support body 100 together with the p-side interconnect part 41 and the n-side interconnect part 43. Since the semiconductor layer 15 is supported by the support body 100, it is possible to remove the substrate 10 therefrom.

For example, the substrate 10, which is a silicon substrate, is removed by we etching or dry etching. Alternatively, in the case where the substrate 10 is a sapphire substrate, the substrate 10 may be removed using the laser lift-off method.

The semiconductor layer 15 on the substrate 10 may contain a large internal stress that is induced in the epitaxial growth process. The material of the p-side metal pillar 23, the n-side metal pillar 24, and the resin layer 25 is flexible compared to the semiconductor layer 15 of the GaN-based material. Then, the p-side metal pillar 23, the n-side metal pillar 24, and the resin layer 25 may absorb the stress, which is released while removing the substrate 10. Thereby, it is possible to avoid breakage of the semiconductor layer 15 in the removing process of the substrate 10.

As shown in FIG. 9B, the first side 15a of the semiconductor layer 15 is exposed after removing the substrate 10. The fine structure with inequalities is formed on the exposed surface of the semiconductor layer 15 on the first side 15a. For example, the semiconductor layer 15 is subjected to we etching using a KOH (potassium hydroxide) solution, TMAH (tetra methyl ammonium hydroxide), or the like. The etching rate depending on the crystal face orientation may form the fine structure with the inequalities on the exposed surface on the first side 15a. The fine structure formed on the first side 15a may improve the extraction efficiency of the light emitted from the light emitting layer 13.

Next, the insulating film 19 is formed on the exposed surface of the semiconductor layer 15 on the first side 15a. The insulating film 19 is, for example, a silicon oxide film formed by using the sputter method. As described previously, the silicon oxide film formed by using the sputter method has a higher density compared to the density of the silicon oxide film formed by using, for example, the PECVD method. In other words, the insulating film 19 is formed so that a density thereof becomes higher than the density of the insulating film 18. The insulating film 19 with the higher density makes it possible to cover the fine structure provided on the first side 15a in a conformal manner.

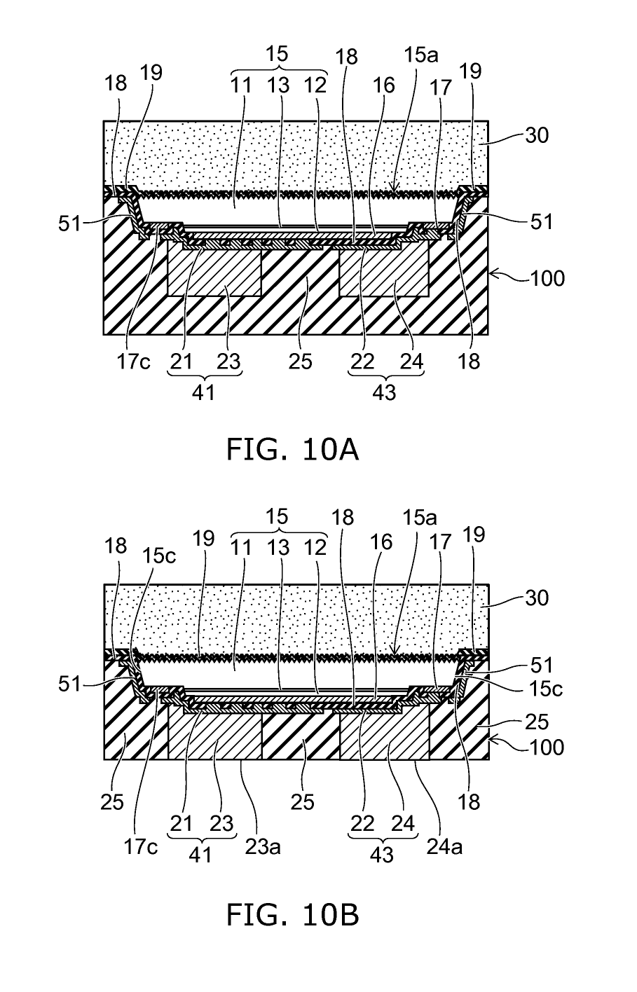

Subsequently, as shown in FIG. 10A, the phosphor layer 30 is formed on the first side 15a via the insulating film 19. The phosphor layer 30 is formed by methods, for example, such as printing, potting, mold, and compression molding. The insulating film 19 may enhance adhesion between the semiconductor layer 15 and the phosphor layer 30. Alternatively, it may also be possible to use a sintered phosphor for the phosphor layer 30. The sintered phosphor may be obtained by combining phosphor particles with a bonding material, and adhered to the semiconductor layer 15 via the insulating film 19.

The phosphor layer 30 may extends from the side surface 15c around the semiconductor layer 15. The resin layer 25 is provided also around the side surface 15c of the semiconductor layer 15. The phosphor layer 30 is formed via the insulating films 18 and 19 on the resin layer 25.

After forming the phosphor layer 30, the surface of the resin layer 25 (lower face in FIG. 10A) is ground to expose the p-side metal pillar 23 and the n-side metal pillar 24 therein as shown in FIG. 10B. The exposed face of the p-side metal pillar 23 serves as the p-side external terminal 23a, and the exposed face of the n-side metal pillar 24 serves as the n-side external terminal 24a.

Next, the structure shown in FIG. 10B is cut along the groove 90 formed for separating the semiconductor layers 15. In other words, the semiconductor light emitting devices 1 joined in the form of a wafer is cut into chips thereof. The phosphor layer 30, the insulating film 19, the insulating film 18, and the resin layer 25 are cut between the adjacent semiconductor layers 15 using, for example, a dicing blade or laser light.

The semiconductor layer 15 does not exist in the groove 90, and thus, does not suffer any damage due to dicing. Further, in the embodiment, it is possible to suppress peeling of the phosphor layer 30 while dicing. For example, in the case where the insulating film 18 and the insulating film 19 are formed to have the same density, there may be a case where the phosphor layer 30 is peeled off by the dicing blade due to entanglement therebetween. The inventors of the application has found out that the peeling of the phosphor layer 30 is suppressed when forming the insulating film 18 and the insulating film 19 to have different densities from each other. Then, it becomes possible to improve the manufacturing yield of the semiconductor light emitting device 1.

As described above, each process before dicing is performed in the wafer state including a plurality of the semiconductor layers 15. The wafer is diced into chips such that the semiconductor light emitting device includes at least one semiconductor layer 15. The semiconductor light emitting device may have a single chip structure including one semiconductor layer 15 or a multichip structure including at least two of the semiconductor layers 15.

Each process before dicing is performed in the wafer state, and thus, there is no need for the individual devices to form interconnections and pillars, to seal in a resin package, and to provide a phosphor layer, and it is possible to improve the manufacturing cost with significant reduction.

Since the dicing is carried out after forming the support body 100 and the phosphor layer 30 in the wafer state, the side surface of the phosphor layer 30 aligns with the side surface of the support body 100 (i.e. the side surface of the resin layer 25), and there side surfaces form the side surfaces of the semiconductor light emitting device. Thus, it is possible to provide a compact semiconductor light emitting device having a chip size package structure without the substrate.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor light emitting device comprising:
a semiconductor layer having a first side and a second side opposite to the first side, and including a first conductivity type layer, a second conductivity type layer, and a light emitting layer between the first conductivity type layer and the second conductivity type layer;
a first interconnect part provided on the second side and electrically connected to the first conductivity type layer;
a second interconnect part provided on the second side and electrically connected to the second conductivity type layer;
a first insulating film between the semiconductor layer and the first interconnect part, and between the semiconductor layer and the second interconnect part; and
a second insulating film in contact with the semiconductor layer on the first side, and having a density different from a density of the first insulating film.

2. The device according to claim 1, wherein the second insulating film has the density higher than the density of the first insulating film.

3. The device according to claim 2, wherein the first insulating film and the second insulating film include silicon atoms, and a density of silicon atoms in the second insulating film is higher than a density of silicon atoms in the first insulating film.

4. The device according to claim 3, wherein an average distance between the silicon atoms in the second insulating film is narrower than an average distance between the silicon atoms in the first insulating film.

5. The device according to claim 3, wherein each of the first insulating film and the second insulating film includes one of a silicon oxide film, a silicon nitride film, and an aluminum oxide film.

6. The device according to claim 1, wherein
the semiconductor layer has a light-emitting part including the light emitting layer and a non light-emitting part not including the light emitting layer, and
the first insulating film covers the light-emitting part and the non light-emitting part on the second side.

7. The device according to claim 6, further comprising:
a first electrode provided on the non light-emitting part on the second side; and
a second electrode provided on the light-emitting part on the second side,
wherein
the first insulating film covers the first electrode and the second electrode,
the first interconnect part is electrically connected to the first electrode through the first insulating film, and communicated with the first electrode, and
the second interconnect part is electrically connected to the second electrode through the first insulating film, and communicated with the second electrode.

8. The device according to claim 1, wherein the first insulating film contacts the second insulating film around the semiconductor layer.

9. The device according to claim 1, wherein whole of the semiconductor layer is covered with the first insulating film and the second insulating film.

10. The device according to claim 1, wherein
the semiconductor layer has a side surface between the first side and the second side, and
the first insulating film covers the side surface.

11. The device according to claim 10, further comprising a metal film covering the side surface via the first insulating film.

12. The device according to claim 1, wherein
the semiconductor layer has inequalities provided on the first side, and
the second insulating film covers the inequalities.

13. The device according to claim 1, further comprising a phosphor layer provided on the semiconductor layer via the second insulating film on the first side, and including a phosphor that emits light having a wavelength different from a wavelength of light emitted from the light emitting layer.

14. The device according to claim 13, further comprising a resin layer covering the first insulating film, the first interconnect part, and the second interconnect part,
wherein the first insulating film and the second insulating film are provided between the phosphor layer and the resin layer around the semiconductor layer.

15. A method of manufacturing a semiconductor light emitting device, comprising:
selectively forming a semiconductor layer on a substrate;
forming a first insulating film covering a structure on the substrate, the structure including the semiconductor layer;
removing the substrate to expose a surface of the semiconductor layer; and
forming a second insulating film being in contact with the surface of the semiconductor layer, and having a density different from a density of the first insulating film.

16. The method according to claim 15, wherein the second insulating film is formed by using a method different from a method of forming the first insulating film.

17. The method of manufacturing a semiconductor device according to claim 16, wherein
the first insulating film is formed by using Chemical Vapor Deposition, and
the second insulating film is formed by using sputtering.
